(19) United States
(12) Patent Application Publication
(10) Pub. No.: US 2013/0292813 A1
(43) Pub. Date: Nov. 7, 2013

(54) MULTI-CHIP FLIP CHIP PACKAGE AND MANUFACTURING METHOD THEREOF

(71) Applicant: RICHTEK TECHNOLOGY CORPORATION, Zhubei City (TW)

(72) Inventor: Yu-Lin YANG, Penghu County (TW)

(73) Assignee: Richtek Technology Corporation, Zhubei City (TW)

(21) Appl. No.: 13/887,410

(22) Filed: May 6, 2013

(30) Foreign Application Priority Data
May 7, 2012 (TW) 101116280

(51) Int. Cl. H01L 21/50; H01L 23/495

(52) U.S. Cl. CPC H01L 21/50; H01L 23/49575
USPC 257/676; 438/108

(57) ABSTRACT

A multi-chip flip chip package includes multiple dies. Each die comprises several pads for coupling with pads of the other die and for coupling with pins of the multi-chip flip chip package through conducting elements. A dielectric element is positioned between the dies and the conducting elements, and positioned between the dies for providing the electrical insulation. The dies and the conducting elements between the dies are coated with a packaging element for preventing physical damage and corrosion.

### CROSS-REFERENCE TO RELATED APPLICATIONS

This application claims the benefit of priority to Patent Application No. 101116280, filed in Taiwan on May 7, 2012, the entirety of which is incorporated herein by reference for all purposes.

### BACKGROUND

The disclosure generally relates to a flip chip package and, more particularly, to the flip chip package encapsulating multiple dies.

With the advances in the semiconductor technology, more and more circuit elements may be integrated in a die (also known as chip). For example, a “system on a chip (SoC)” may integrate most of the required circuit elements of a system into a die. The SoC, however, often requires several types of circuit elements, e.g., analog circuits, digital circuits, and memory units. The various and complicated manufacturing processes of the circuit elements greatly limit the yield rate of the SoC and increase the design complexity and the hardware cost.

In the “system in package (SiP)” approaches, circuit elements are fabricated into several dies which are encapsulated in a single package. In many SiP approaches, the dies are positioned on a circuit board substrate comprising several layers located on different planes, and the dies are coupled by utilizing wires routed through the layers. Packages encapsulated with the circuit board substrate often occupy larger areas, and the packaging process is more complicated.

Moreover, the dimensions of the wires and the circuit board substrate are often limited, e.g., the thickness of the circuit board substrate is often several micrometers or less. Accordingly, the current carrying capability is confined by the dimensions of the wires and the heat dissipating capability is confined by the dimensions of the circuit board. The package encapsulating the circuit board substrate therefore requires additional mechanisms to dissipate the heat. In other approaches, the die may be encapsulated with a lead frame of a thickness ranging from tens of micrometers to hundreds of micrometers. The current carrying capability and the heat dissipating capability of the lead frame are greatly superior to the circuit board substrate. Multiple dies, however, are not easily and accurately interconnected when encapsulated with the lead frame.

In some applications, the dies are encapsulated in a single package by the flip chip packaging process, and interconnected by utilizing one or more clips. The clip is formed by etching or cutting the metal into the required shape and coupled with the pads of the dies. Because the dimensions of the pads are often are very small, the clips cannot be accurately positioned on the pads. Complicated packaging processes must be done to accurately interconnect the dies in the flip chip package process.

In more and more applications, the dies require lots of interconnections, e.g., the connections between the memory unit and the memory controller. If the dies cannot be interconnected in the package, a large amount of wires must be routed outside the package. The number of the package pins and therefore the package size increase. Accordingly, the hardware complexity and the hardware cost outside the package may not be effectively reduced.

### SUMMARY

In view of the foregoing, it may be appreciated that a substantial need exists for methods and apparatuses that mitigate or reduce the problems above.

An example embodiment of a method for manufacturing a multi-chip flip chip package is disclosed, comprising: attaching a second surface of a first die and a second surface of a second die to a second substrate; positioning a first dielectric element between the first die and the second die; coupling a plurality of conducting elements of a first conducting group with at least part of pads on a first surface of the first die, and with at least part of pads on a first surface of the second die; coupling at least part of the pads on the first surface of the first die with at least part of the pads on the first surface of the second die by utilizing a plurality of conducting elements of a second conducting group; coupling at least part of the conducting elements of the first conducting group with strips of a lead frame; and coating the first die, the second die, and the conducting elements of the second conducting group with a packaging element.

Another example embodiment of a method for manufacturing a multi-chip flip chip package is disclosed, comprising: attaching a second surface of a first die and a second surface of a second die to a second substrate; positioning a first dielectric element between the first die and the second die; coupling a plurality of conducting elements of a first conducting group with at least part of pads on a first surface of the first die, and with at least part of pads on a first surface of the second die; coupling at least part of the pads on the first surface of the first die with at least part of the pads on the first surface of the second die by utilizing a plurality of conducting elements of a second conducting group; and coupling at least part of the conducting elements of the first conducting group with pins of the multi-chip flip chip package.

An example embodiment of a multi-chip flip chip package is disclosed, comprising: a first die, comprising a first surface, a second surface, and pads positioned on the first surface of the first die; a second die, comprising a first surface, a second surface, and pads positioned one the first surface of the second die; a first dielectric element, positioned between the first die and the second die; a first conducting group, comprising a plurality of conducting elements for coupling with at least part of the pads of the first die and for coupling with at least part of the pads of the second die; a second conducting group, comprising a plurality of conducting elements for coupling at least part of the pads of the first die with at least part of the pads of the second die; and a plurality of pins, coupled with the conducting elements of the first conducting group.

Both the foregoing general description and the following detailed description are examples and explanatory only, and not restrictive of the invention as claimed.

### BRIEF DESCRIPTION OF THE DRAWINGS

FIG. 1 shows a simplified flowchart of a multi-chip flip chip package manufacturing method according to one embodiment of the present disclosure.

FIGS. 2, 4, 6, 8, 10, 12, 15 and 17 respectively show a simplified top view of a multi-chip flip chip package during the manufacturing process according to the present disclosure.

FIGS. 3, 5, 7, 9, 11, 13, 16 and 18 respectively show a simplified sectional view of the multi-chip flip chip package during the manufacturing process according to the present disclosure.

FIG. 14 shows a simplified flowchart of another multi-chip flip chip package manufacturing method according to another embodiment of the present disclosure.

### DETAILED DESCRIPTION

Reference is made in detail to embodiments of the invention, which are illustrated in the accompanying drawings. The same reference numbers may be used throughout the drawings to refer to the same or like parts, components, or operations.

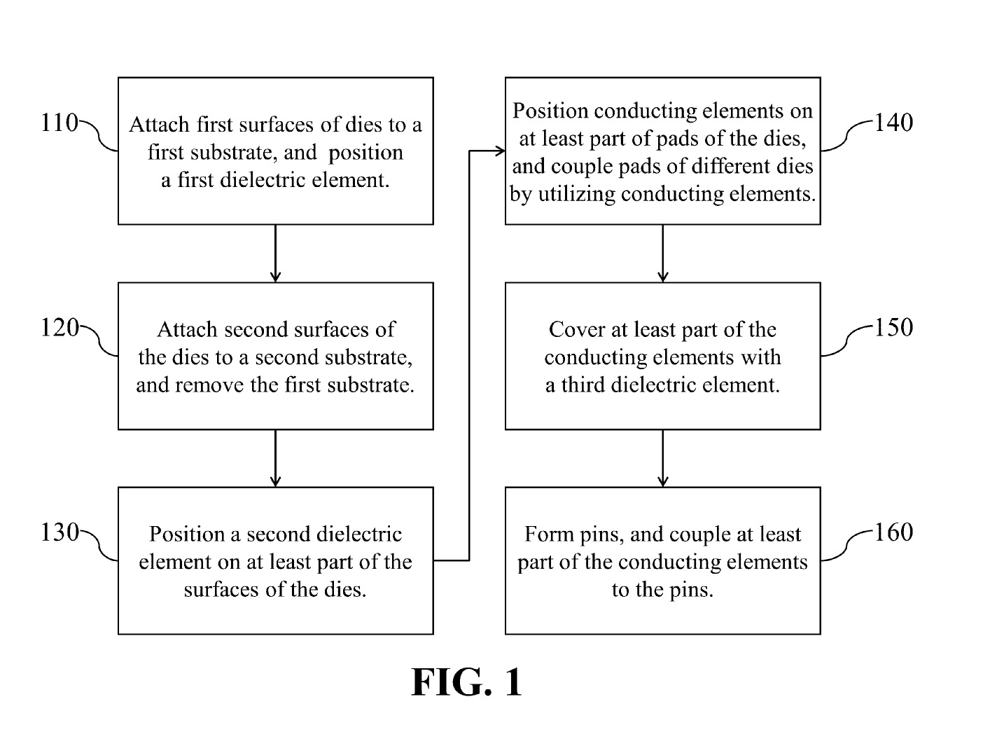

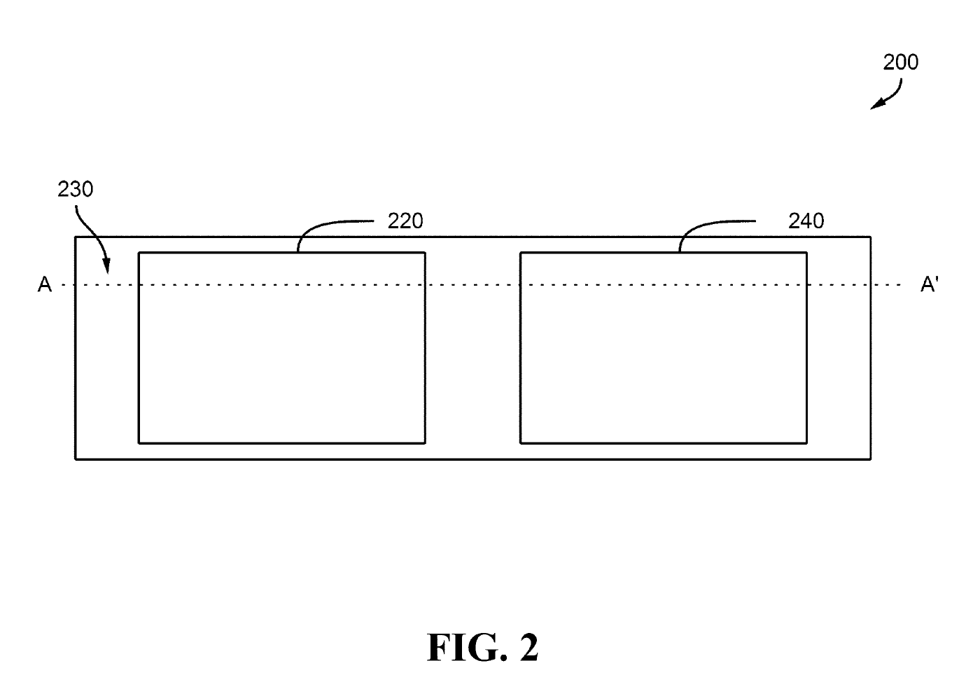

FIG. 1 shows a simplified flowchart of a multi-chip flip chip package manufacturing method according to one embodiment of the present disclosure. FIGS. 2-13 respectively show simplified top views and sectional views of a multi-chip flip chip package during the manufacturing process according to the method in FIG. 1. The multi-chip flip chip package and the manufacturing method thereof are further explained below with FIGS. 1-13. For the purposes of conciseness and clear explanation, some components and connections thereof are not shown in the drawings.

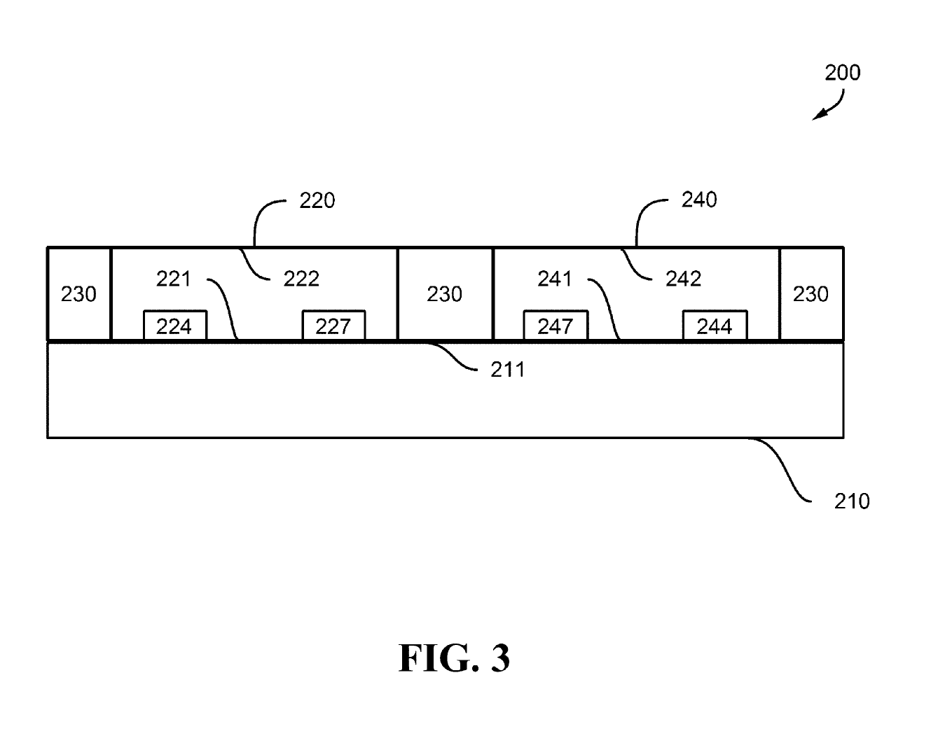

Please refer to FIGS. 2 and 3. FIG. 2 shows a simplified top view of a multi-chip flip chip package 200, and FIG. 3 shows a simplified sectional view of the multi-chip flip chip package 200 along the line A-A′ in FIG. 2. In the operation 110 in FIG. 1, a first surface 221 of a first die 220 and a first surface 241 of a second die 240 are attached to a first surface 211 of a first substrate 210. In FIG. 3, there are two pads 224 and 227 located on the first surface 221 of the first die 220, and two pads 244 and 247 located on the first surface 241 of the second die 240. For example, the first die 220 and the second die 240 may be attached to the first substrate 210 by utilizing one or more adhesive materials. The substrate 210 may be made of metallic materials, plastic materials, or other materials with a sufficient hardness for supporting the dies 220 and 240. The surface 211 of the substrate 210 is configured to be substantially flat so that the pads 224, 227, 244, and 247 may be positioned on the same plane for being coupled with conducting elements more easily. Moreover, in the operation 110, a first dielectric element 230 is position around the dies 220 and 240 for forming the multi-chip flip chip package 220. In this embodiment, the dielectric element 230, the surface 222 of the first die 220, and the surface 242 of the second die 240 are located on substantially the same plane so as to be attached to a second substrate 410 more easily in the following process.

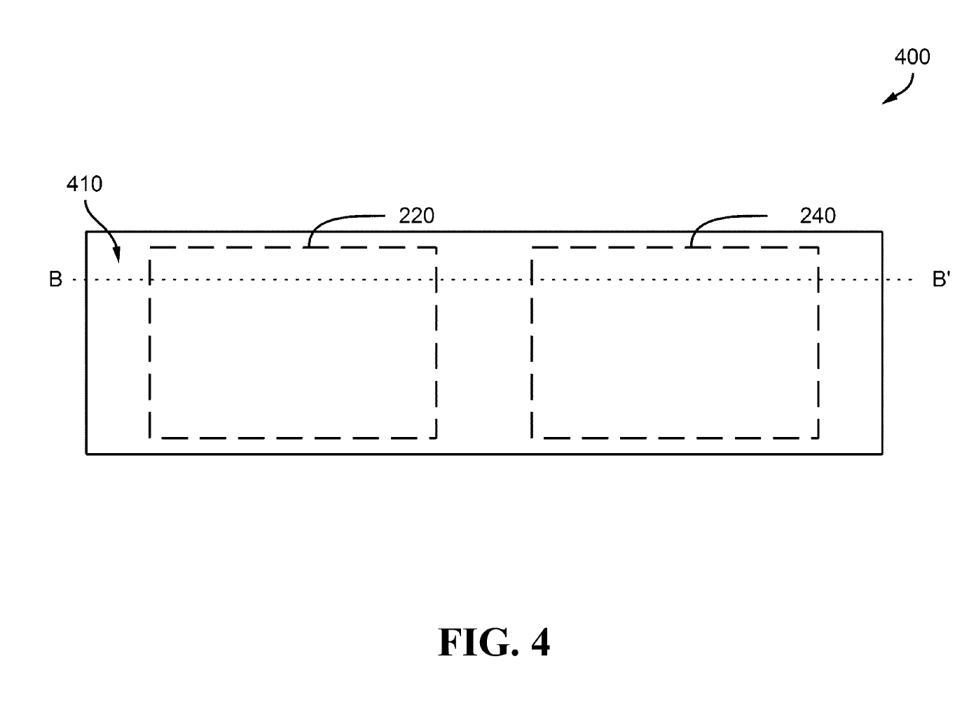

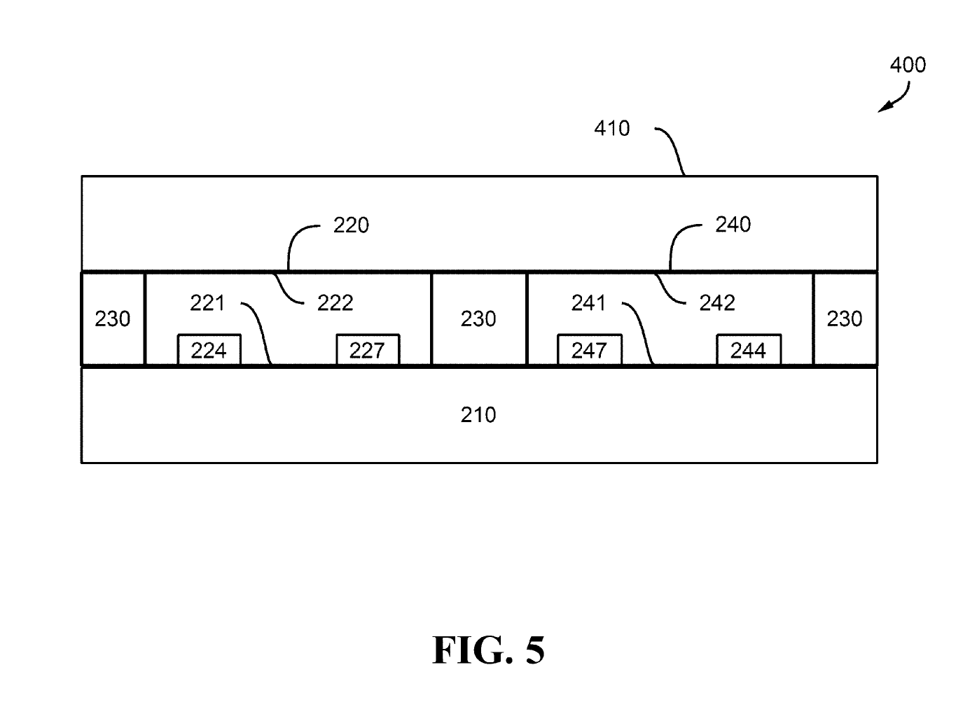

Please refer to FIGS. 4 and 5. FIG. 4 shows a simplified top view of a multi-chip flip chip package 400, and FIG. 5 shows a simplified sectional view of the multi-chip flip chip package 400 along the line B-B′ in FIG. 4. In the operation 120 in FIG. 1, the dielectric element 230, the second surface 222 of the first die 220, and the second surface 242 of the second die 242 of the multi-chip flip chip package 200 are attached to the second substrate 410 for forming the multi-chip flip chip package 400. The substrate 410 may be made of metallic materials, plastic materials, or other materials with a sufficient hardness. After the dies 220 and 240 were attached to the second substrate 410, the first substrate 210 is removed by etching, grinding, lapping, polishing, slicing, other suitable physical means and/or other suitable chemical means. In FIG. 4 and the following drawings, the positions of the dies 220 and 240 are denoted by the dashed rectangles when the dies 220 and 240 may not directly be seen.

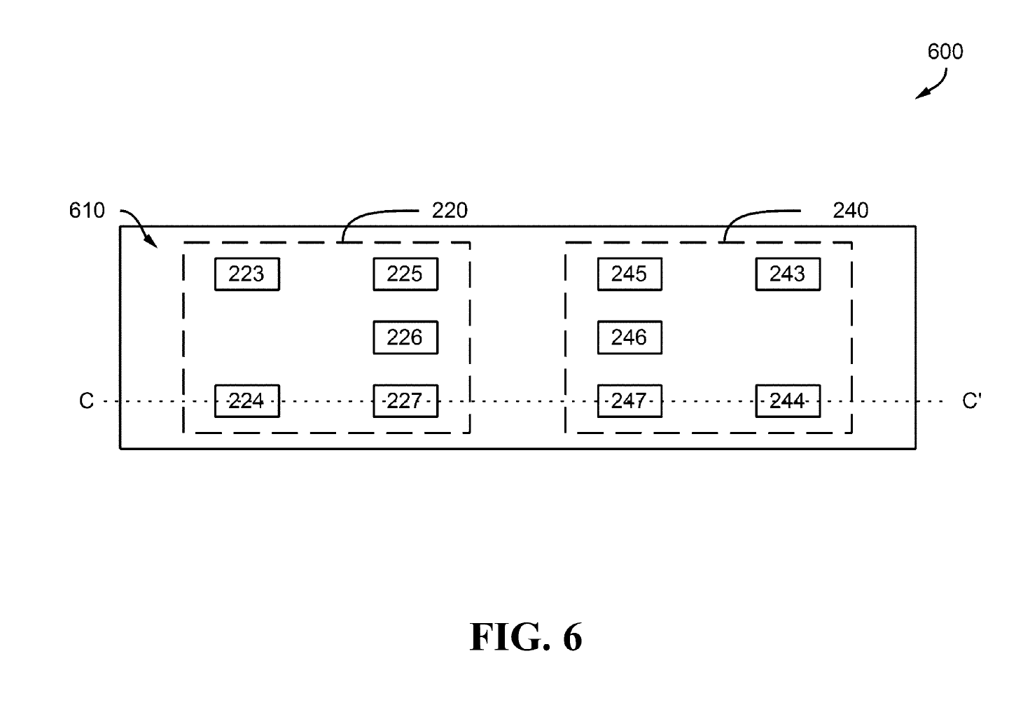

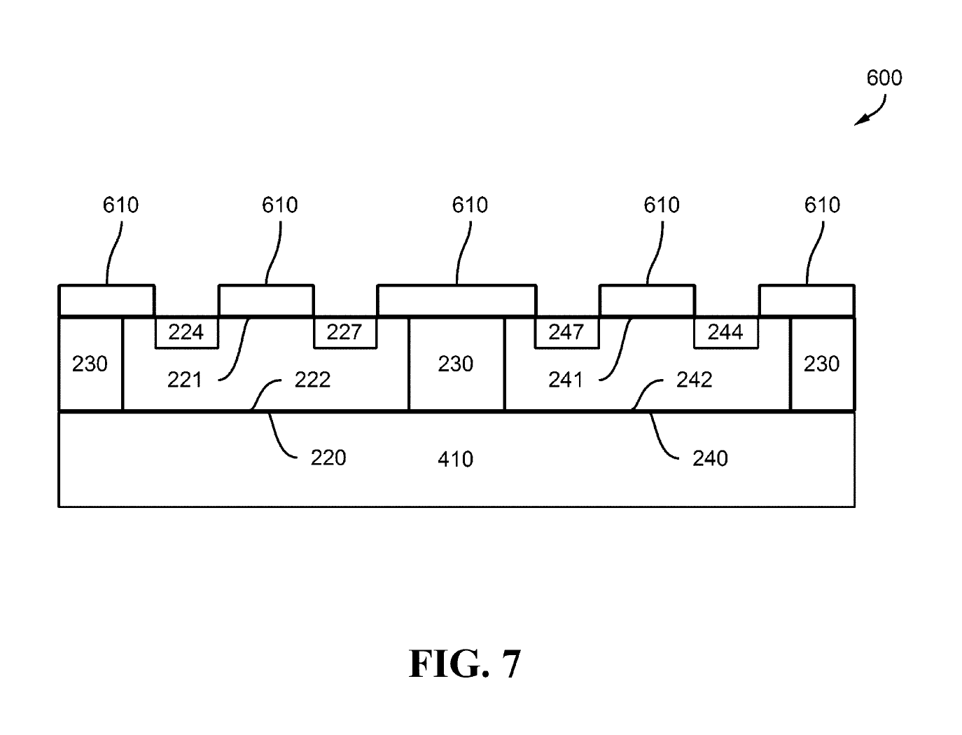

Please refer to FIGS. 6 and 7. FIG. 6 shows a simplified top view of a multi-chip flip chip package 600, and FIG. 7 shows a simplified sectional view of the multi-chip flip chip package 600 along the line C-C′ in FIG. 6. The multi-chip flip chip package 400 is turned upside down so that the surface 221 of the die 220 and the surface 241 of the die 240 are on the top in FIGS. 6 and 7. In the operation 130 in FIG. 1, the second dielectric element 610 is positioned on at least part of the surface 221 of the die 220 and at least part of the surface 241 of the die 240 for forming the multi-chip flip chip package 600. In this embodiment, the pads 223˜227 and 243˜247 are not covered or not completely covered by the second dielectric element 610, and other areas on the surfaces 221 and 241 are completely covered by the second dielectric element 610.

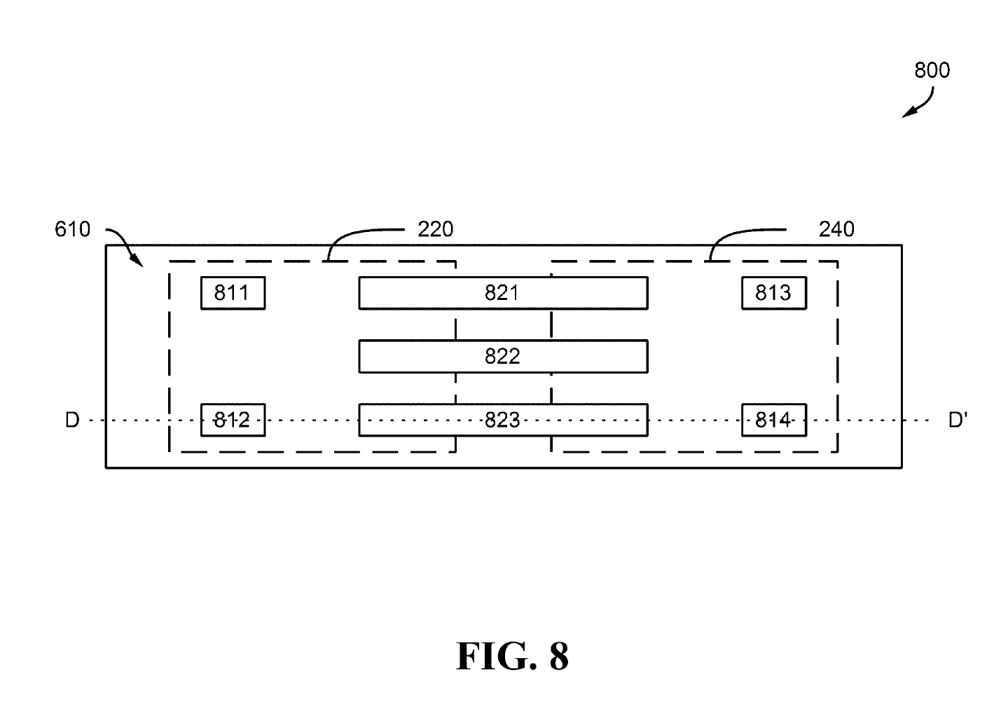

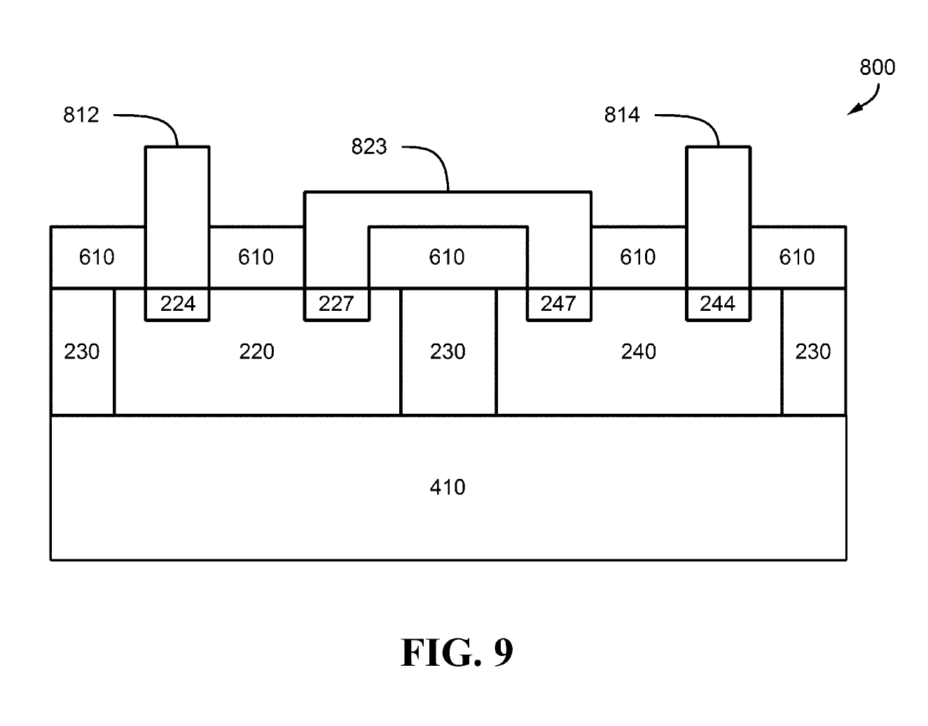

Please refer to FIGS. 8 and 9. FIG. 8 shows a simplified top view of a multi-chip flip chip package 800, and FIG. 9 shows a simplified sectional view of the multi-chip flip chip package 800 along the line D-D′ in FIG. 8. In the operation 140 in FIG. 1, conducting elements 811˜814 of a first conducting group are respectively positioned on the pads 223, 224, 243, and 244. The pads 225 and 245, the pads 226 and 246, and the pads 227 and 247 are respectively coupled by utilizing conducting elements 821, 822, and 823 of a second conducting group. Accordingly, the multi-chip flip chip package 800 is formed.

In practical implementations, the conducting elements 821˜823 may be respectively realized with conducting materials of any suitable shape and any suitable size for coupling the pads 225 and 245, the pads 226 and 246, and the pads 227 and 247. Moreover, the conducting elements 821˜823 are positioned on the same plane, which is obviously different from and simpler than the system in package (SiP) technique. The SiP technique utilizes a circuit board substrate comprising several layers located on different planes, and couples pads of different dies by routes the conducting elements through the layers.

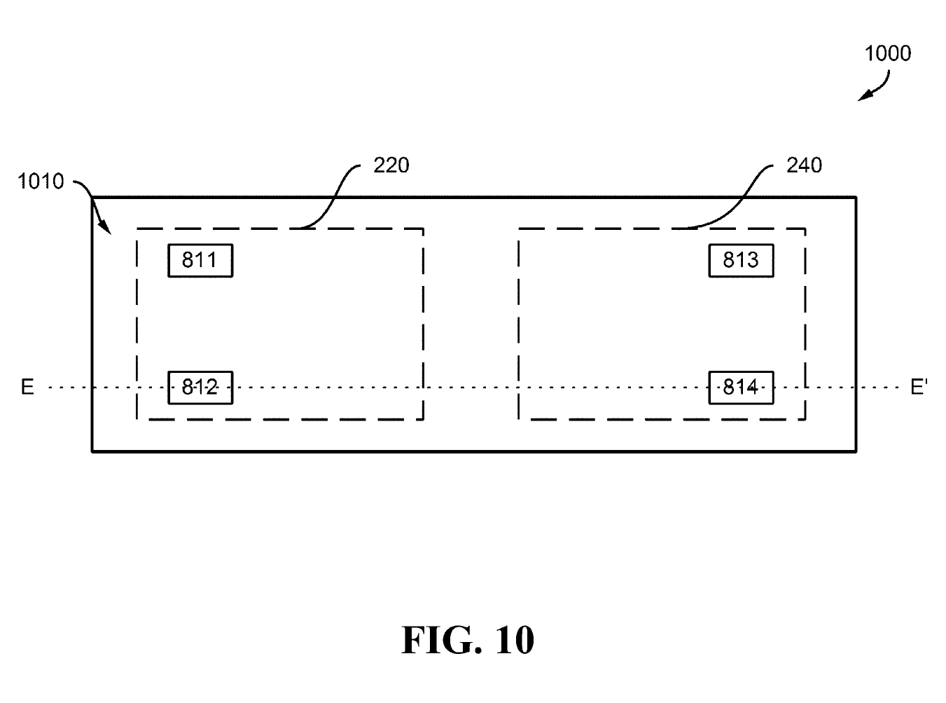

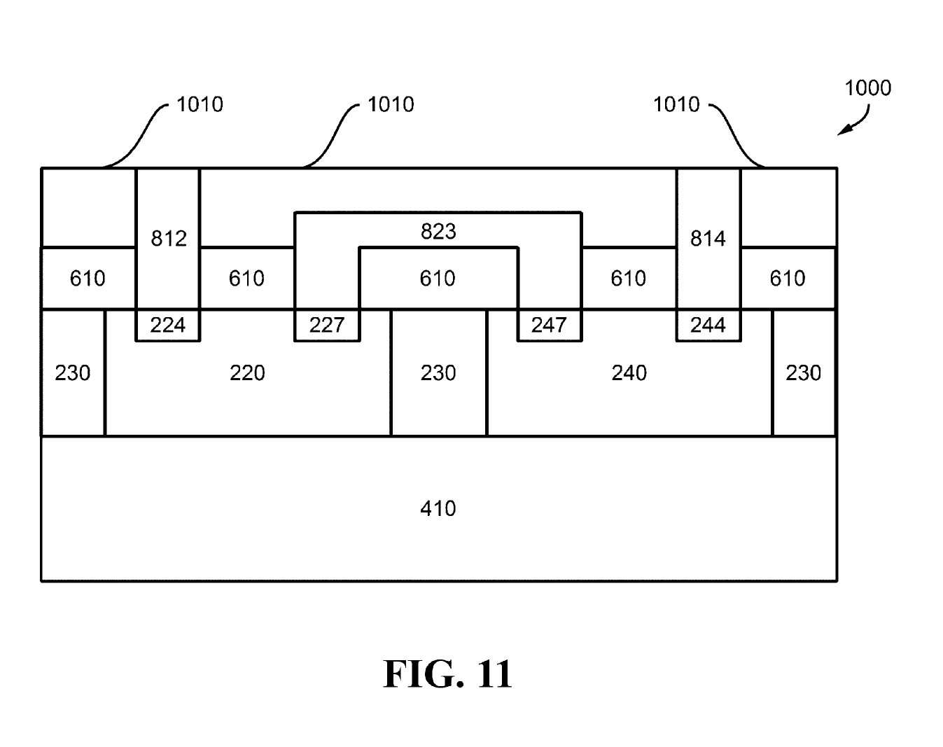

Please refer to FIGS. 10 and 11. FIG. 10 shows a simplified top view of a multi-chip flip chip package 1000, and FIG. 11 shows a simplified sectional view of the multi-chip flip chip package 1000 along the line E-E′ in FIG. 10. In the operation 150 in FIG. 1, the third dielectric element 1010 is positioned on the second dielectric element 610 and the conducting elements 821˜823 for forming the multi-chip flip chip package 1000. The conducting elements 821˜823 for coupling the pads of the dies 220 and 240 are therefore covered by the third dielectric element 1010. Moreover, the conducting elements 811˜814, respectively positioned on the pads 223, 224, 243, and 244, are not completely covered by the third dielectric element 1010.

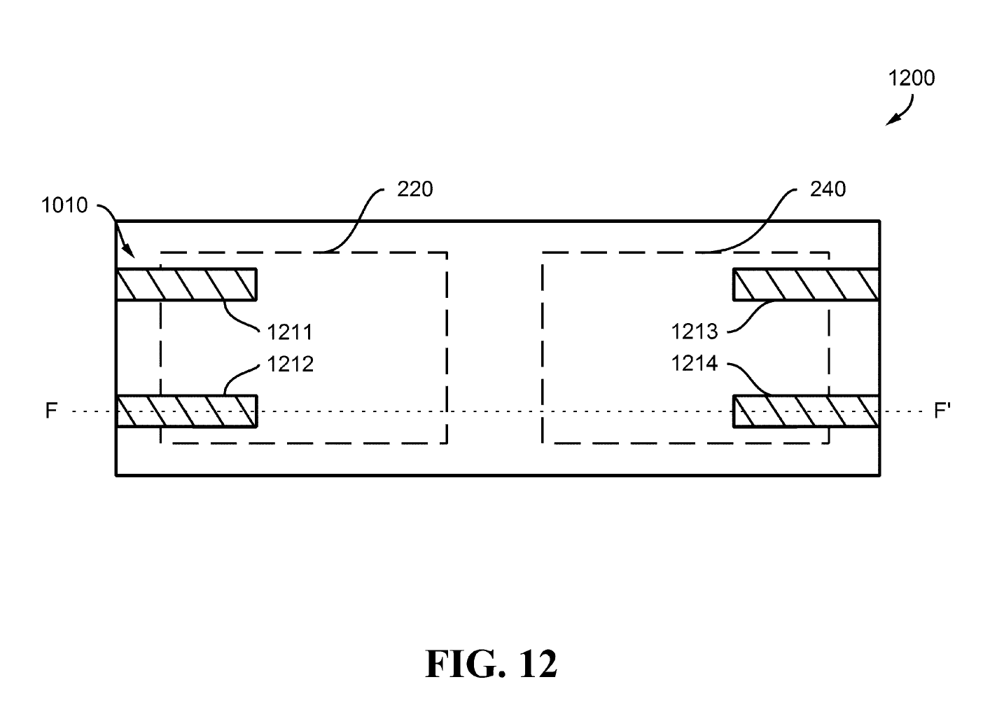

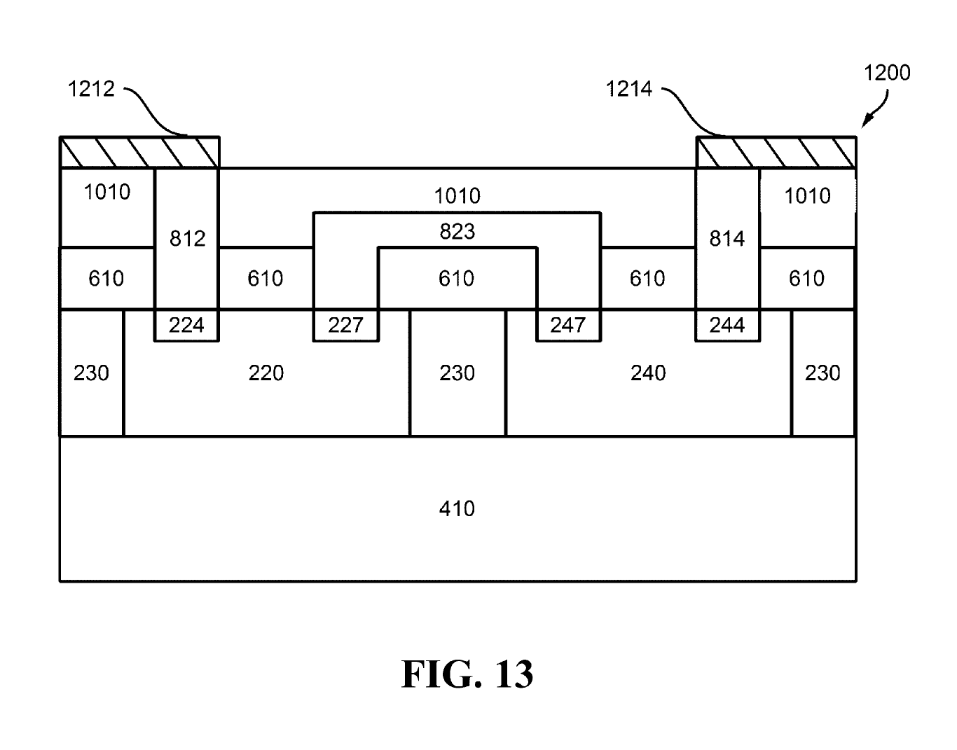

Please refer to FIGS. 12 and 13. FIG. 12 shows a simplified top view of a multi-chip flip chip package 1200, and FIG. 13 shows a simplified sectional view of the multi-chip flip chip package 1200 along the line F-F′ in FIG. 12. In the operation 160 in FIG. 1, pins 1211˜1214 (only pins 1212 and 1214 are shown in FIG. 13) are formed by electroplating and respectively coupled with the conducting elements 811˜814. For example, the pins 1211˜4214 may be made of copper, gold, tin, alloys, and/or other suitable conducting materials. The multi-chip flip chip package 1200 may be coupled with other circuit elements and/or a circuit board by utilizing the pins 1211˜1214.

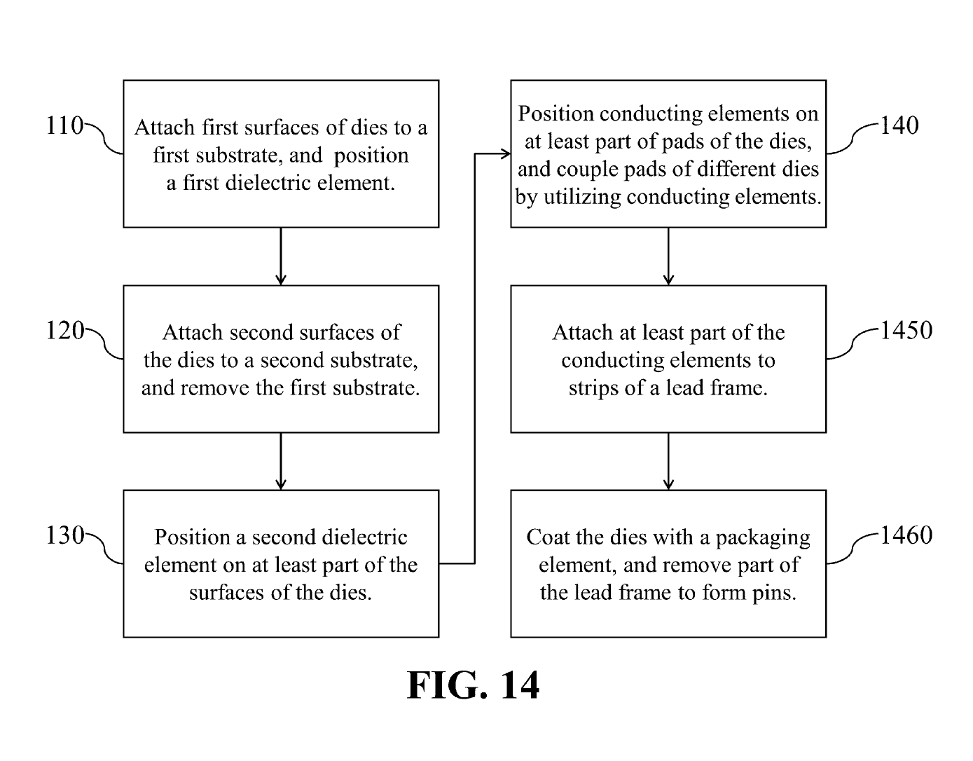

FIG. 14 shows a simplified flowchart of another multi-chip flip chip package manufacturing method according to another embodiment of the present disclosure. The operations 110˜140 in FIG. 14 are substantially the same as the operations 110˜140 in FIG. 1, and the description thereof is omitted for conciseness. FIGS. 2˜9 and 15˜18 respectively show simplified top views and sectional views of a multi-chip flip chip package during the manufacturing process according to the method in FIG. 14. The multi-chip flip chip package and the manufacturing method thereof are further explained below with FIGS. 2˜9 and 14˜18. For the purposes of conciseness and clear explanation, some components and connections thereof are not shown in the drawings.

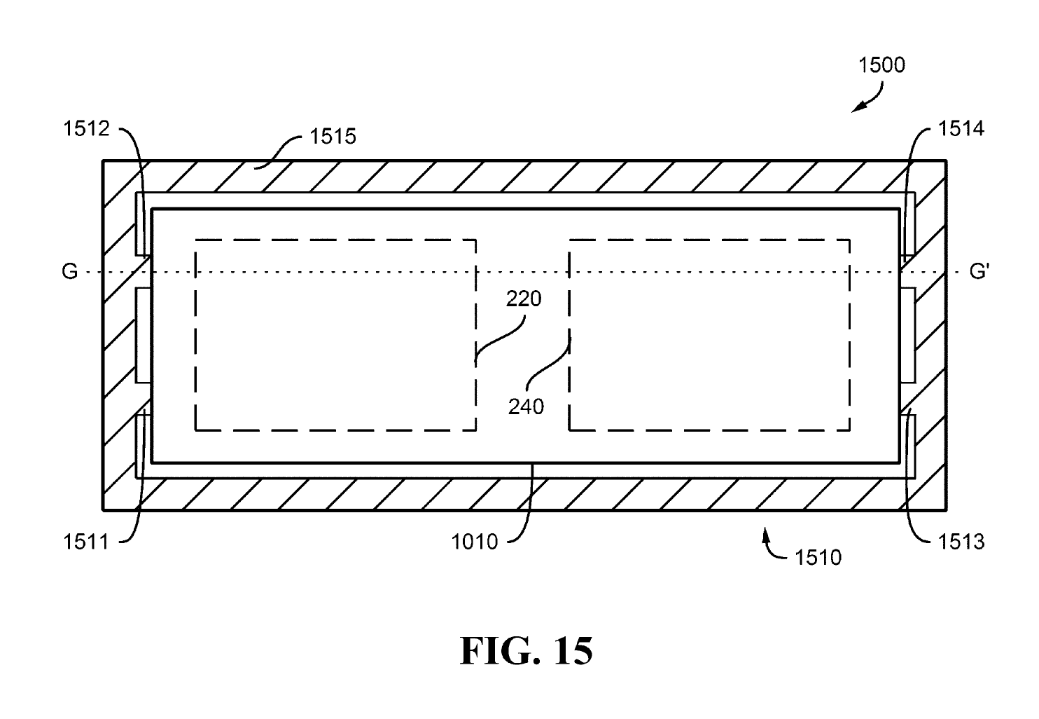

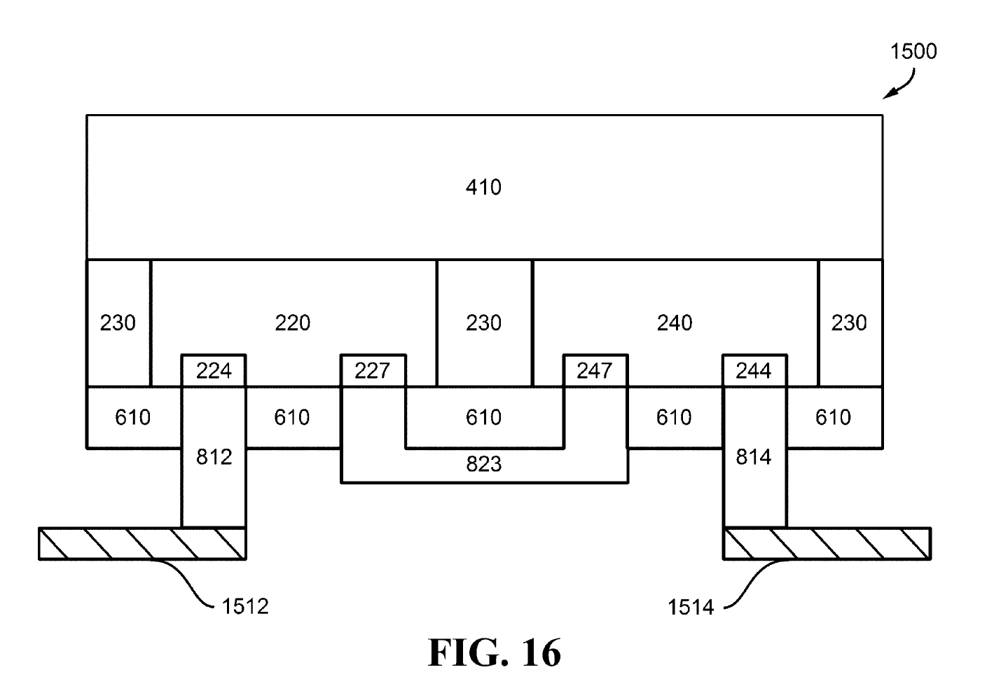

Please refer to FIGS. 15 and 16. FIG. 15 shows a simplified top view of a multi-chip flip chip package 1500, and FIG. 16 shows a simplified sectional view of the multi-chip flip chip package 1500 along the line G-G′ in FIG. 15. The multi-chip flip chip package 1500 is formed by turning the multi-chip flip chip package 800 upside down for positioning on a lead frame 1510. The lead frame 1510 comprises several strips 1511˜4514 and a frame 1515. In the operation 1450 in FIG. 14, the conducting elements 811˜814, respectively coupled with the pads 223, 224, 243, and 244, are respectively attached to the strips 1511˜1514 of the lead frame 1510 for forming the multi-chip flip chip package 1500. For example, the conducting elements 811˜814 may be attached to the strips 1511˜4514 by utilizing tin, electrically conductive adhesives, or other suitable conducting materials. In practical implementations, when the conducting elements 811˜814 are made of tin or other low melting point metals, the multi-chip flip chip package 1500 may be formed by melting and attaching the conducting elements 811˜814 to the lead frame 1510.

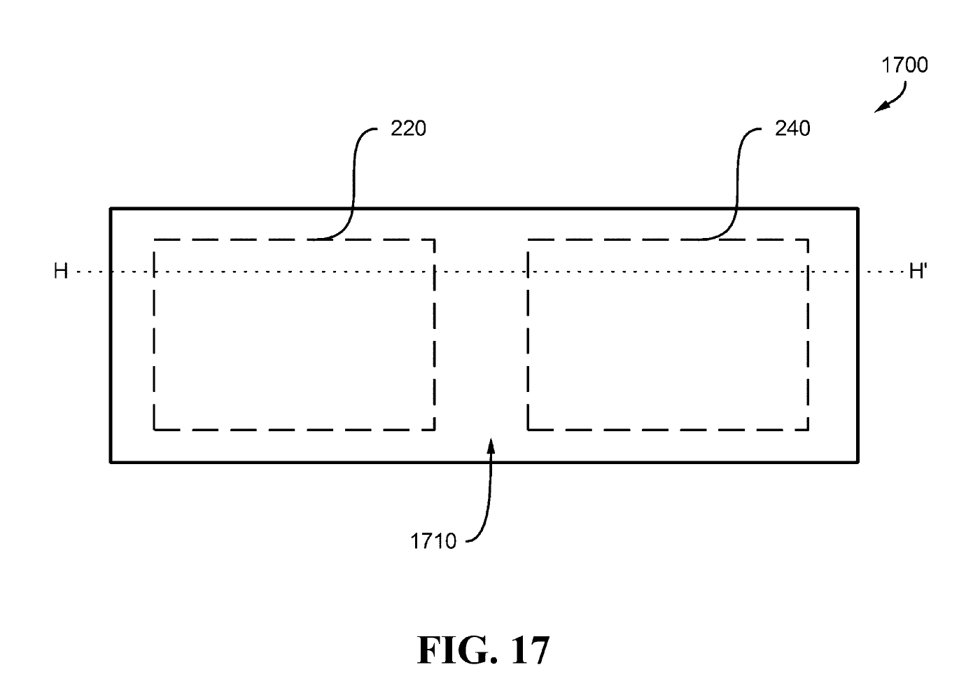

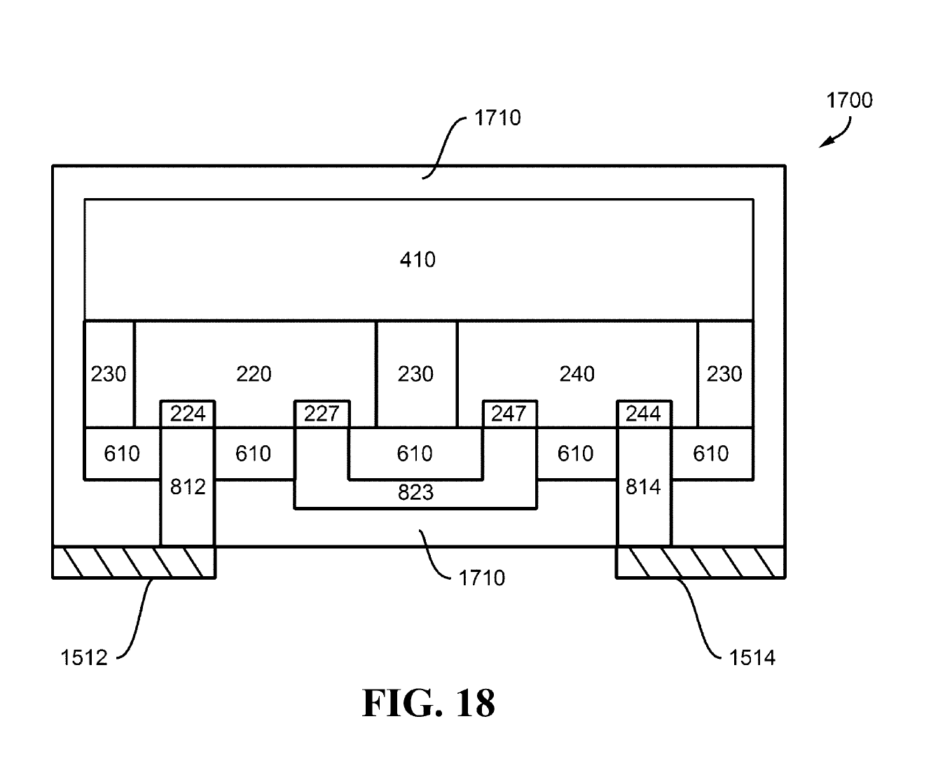

Please refer to FIGS. 17 and 18. FIG. 17 shows a simplified top view of a multi-chip flip chip package 1700, and FIG. 18 shows a simplified sectional view of the multi-chip flip chip package 1700 along the line H-H′ in FIG. 17. In the operation 1460 in FIG. 14, the multi-chip flip chip package 1700 is formed by coating the multi-chip flip chip package 1500 with a packaging element 1710 and removing the frame 1515 of the lead frame 1510. The residual strips 1511˜1514 of the lead frame 1510 may be utilized as pins of the multi-chip flip chip package 1700. The multi-chip flip chip package 1700 may be coupled with other circuit elements and/or a circuit board by utilizing the pins 1511˜1514.

In the operation 110 in other embodiments, the dielectric element 230 may be positioned over at least part of the surface 222 of the die 220 and/or at least part of the surface 242 of the die 240. Afterward, the excessive portion of the dielectric element 230 over the dies 220 and/or 240 is removed so that the dielectric element 230, the surface 222 of the die 220, and the surface 242 of the die 240 may be located on substantially the same plane.

In the operation 110 in other embodiments, the dielectric element 230 may be positioned over the entire surface 222 of the die 220 and the entire surface 242 of the die 240. Thus, the dielectric element 230 forms a flat plane so as to be attached to the second substrate 410 in the operation 120.

In the operation 130 in other embodiments, the dielectric element 610 may be position over part of the pads 223˜227 of the die 220, and/or over part of the pads 243˜247 of the die 240. Moreover, the pads 223˜227 and 243˜247 still have enough areas to be coupled with the conducting elements 811˜814 and 821˜823.

In the operation 130 in other embodiments, the dielectric element 610 may be positioned over the entire surface 221 of the die 220 and the entire surface 241 of the die 240. Afterward, the dielectric element 610 over the pads 223˜227 and 243˜247 are removed by etching, grinding, lapping, polishing, slicing, other suitable physical means and/or other suitable chemical means.

In the operation 140 in other embodiments, the conducting elements 811˜814 and 821˜823 may respectively comprise the same of different conducting materials.

In other embodiments, when the thicknesses of the dies 220 and 240 are substantially the same, the operations 110˜130 may be further simplified. For example, the surface 222 of the die 220 and the surface 242 of the die 240 are attached to the second substrate 410 without the operations regarding the first substrate 210. The dielectric element 230 is positioned around the dies 220 and 240, and the dielectric element 610 is positioned on suitable places of the surface 221 of the die 220 and the surface 242 of the die 240.

In the operation 1460 in other embodiments, the substrate 410 may be not completely coated by the packaging element 1710. Thus, when the multi-chip flip chip package 1700 is functioning, the heat of the dies 220 and 240 may be dissipated through the second substrate 410.

In the operation 1460 in other embodiments, the second substrate 410 may be removed with physical means and/or chemical means before coating the multi-chip flip chip package with the packaging element 1710.

In the operation 1460 in other embodiments, the fame 1515 of the lead frame 1510 may be configured to be in other suitable geometric shapes. The frame 1515 of the lead frame 1510 may also be not removed or not completely removed according to different design considerations. For example, the fame 1515 of the lead frame 1510 may be removed later when the multi-chip flip chip package is delivered to the customer's factory for preventing physical damage.

In the above embodiments, the dielectric elements 230, 610, and 1010, and the packaging element 1710 may be respectively realized with the same of different electrically insulating materials, e.g., resins, rubber, and polymers.

In the above embodiments, the substrate 410 may be realized with one or more electrically insulating materials, or be equipped with one or more electrically leakage prevention devices for preventing the electrical leakage from the dies 220 and 240 through the substrate 410.

In the above embodiments, the conducting elements 811˜814 and 821˜823 may be respectively realized by printing, sputtering, electroplating, and/or deposition with tin, nickel, copper, silver, or other metals. The conducting elements 811˜814 and 821˜823 may also be respectively realized with graphite, polymer, electrically conductive adhesive, other suitable conductive materials.

In the above embodiments, the lead frame 1510 may be easily realized by etching the metal into the required shape and size. For example, in some embodiments, the thickness of the lead frame 1510 may be configured to range from tens of micrometers to hundreds of micrometers for increasing the current carrying capability.

In some embodiments, the currents transferred between the dies are small compared with the currents transferred through the lead frame 1510. The thickness of the conducting elements 821˜823 may be configured to be less than the thickness of the lead frame 1510.

In the above embodiments, the packaging element 1710 may be realized with resins or other opaque materials.

In the above embodiments, multiple dies may be interconnected and encapsulated in a package by utilizing the flip chip packaging process. The dies are interconnected by conducting elements, and coupled to the lead frame for forming a multi-chip flip chip package. The package size may be effectively reduced because of the flip chip packaging process. Moreover, the dies may be accurately interconnected for performing the communications between the dies in the package. The number of interconnections between the dies in a package may be greatly increased so that more dies may be integrated in a single package according to the embodiments above. The hardware complexity and hardware cost outside the package may be therefore effectively reduced.

Moreover, in the above embodiments, the dies are encapsulated with the lead frame. The performance and the durability of the package may be improved because of the heat dissipation capability and the current carrying capability of the lead frame.

In the description and the claims, the term “element” may be referred to one or more components, layers, regions, or other suitable structures in the practical implementations.

In the drawings, the sizes and relative sizes of some elements may be exaggerated or simplified for clarity. Accordingly, unless the context clearly specifies, the shape, the size, the relative size, and the relative position of each element in the drawings are illustrated merely for clarity and explanation purposes, and not intended to be used to restrict the claim scope.

In the description and the claims, unless a first element is referred to be directly above, over, connected, attached, or coupled to a second element, it means that the first element may be above, over, connected, attached, or coupled to the second element directly or through another intermediate element.

For the purpose of conciseness and clear explanation, some terms may be used to describe the relative positions between the elements, e.g., above, over, under, below, higher than, lower than, upward, and downward. One skilled in the art appreciates that these terms are not used to restrict the claim scope. For example, when the first element is referred to be positioned above the second element, the first element may actually be positioned above, below, or beside the second element in the manufacturing process or in the application.

Certain terms are used throughout the description and the claims to refer to particular components. One skilled in the art appreciates that a component may be referred to as different names. The present disclosure does not intend to distinguish between components that differ in name but not in function. In the description and in the claims, the term “comprise” is used in an open-ended fashion, and thus should be interpreted to mean “include, but not limited to.” The phrases “be coupled with,” “couples with,” and “coupling with” are intended to compass any indirect or direct connection. Accordingly, if the present disclosure mentioned that a first device is coupled with a second device, it means that the first device may be directly or indirectly connected to the second device through electrical connections, wireless communications, optical communications, or other signal connections with/without other intermediate devices or connection means.

The term “and/or” may comprise any and all combinations of one or more of the associated listed items. In addition, the singular forms “a,” “an,” and “the” herein are intended to comprise the plural forms as well, unless the context clearly indicates otherwise.

Other embodiments of the invention will be apparent to those skilled in the art from consideration of the specification and practice of the invention disclosed herein. It is intended that the specification and examples be considered as exemplary only, with a true scope and spirit of the invention indicated by the following claims.

What is claimed is:

1. A method for manufacturing a multi-chip flip chip package, comprising:
attaching a second surface of a first die and a second surface of a second die to a second substrate;
positioning a first dielectric element between the first die and the second die;
coupling a plurality of conducting elements of a first conducting group with at least part of pads on a first surface of the first die, and with at least part of pads on a first surface of the second die;
coupling at least part of the pads on the first surface of the first die with at least part of the pads on the first surface of the second die by utilizing a plurality of conducting elements of a second conducting group;
coupling at least part of the conducting elements of the first conducting group with strips of a lead frame; and
coating the first die, the second die, and the conducting elements of the second conducting group with a packaging element.

2. The method of claim 1, further comprising:
attaching the second surface of the first die and the second surface of the second die to the second substrate after the first surface of the first die and the first surface of the second die were attached to a first substrate; and
removing the first substrate after the first die and the second die were attached to the second substrate.

3. The method of claim 1, further comprising:
coating the first die, the second die, and the conducting elements of the second conducting group with the packaging element after the second substrate was removed.

4. The method of claim 1, further comprising:
removing a frame of the lead frame for configuring the strips of the lead frame to be pins of the multi-chip flip chip package.

5. The method of claim 1, further comprising:
positioning a second dielectric element between the conducting elements of the second conducting group and at least one of the first die and the second die.

6. A method for manufacturing a multi-chip flip chip package, comprising:
attaching a second surface of a first die and a second surface of a second die to a second substrate;
positioning a first dielectric element between the first die and the second die;
coupling a plurality of conducting elements of a first conducting group with at least part of pads on a first surface of the first die, and with at least part of pads on a first surface of the second die;
coupling at least part of the pads on the first surface of the first die with at least part of the pads on the first surface of the second die by utilizing a plurality of conducting elements of a second conducting group; and
coupling at least part of the conducting elements of the first conducting group with pins of the multi-chip flip chip package.

7. The method of claim 6, further comprising:
attaching the second surface of the first die and the second surface of the second die to the second substrate after the first surface of the first die and the first surface of the second die were attached to a first substrate; and
removing the first substrate after the first die and the second die were attached to the second substrate.

8. The method of claim 6, further comprising:
removing the second substrate.

9. The method of claim 6, wherein at least one of the pins of the multi-chip flip chip package is electroplated.

10. The method of claim 6, further comprising:
positioning a second dielectric element between the conducting elements of the second conducting group and at least one of the first die and the second die.

11. The method of claim 6, further comprising:
coating the conducting elements of the second conducting group with a third dielectric element.

12. A multi-chip flip chip package, comprising:
a first die, comprising a first surface, a second surface, and pads positioned on the first surface of the first die;
a second die, comprising a first surface, a second surface, and pads positioned one the first surface of the second die;
a first dielectric element, positioned between the first die and the second die;
a first conducting group, comprising a plurality of conducting elements for coupling with at least part of the pads of the first die and for coupling with at least part of the pads of the second die;
a second conducting group, comprising a plurality of conducting elements for coupling at least part of the pads of the first die with at least part of the pads of the second die; and
a plurality of pins, coupled with the conducting elements of the first conducting group.

13. The multi-chip flip chip package of claim 12, further comprising:
a packaging element coating the first die, the second die, and the conducting elements of the second conducting group;
wherein at least one of the pins is a strip of a lead frame.

14. The multi-chip flip chip package of claim 12, further comprising:
a third dielectric element coating the conducting elements of the second conducting group;
wherein at least one of the pins is electroplated.

15. The multi-chip flip chip package of claim 12, wherein the conducting elements of the second conducting group are positioned on a same plane.

16. The multi-chip flip chip package of claim 12, further comprising:
a second dielectric element positioned between the conducting elements of the second conducting group and at least one of the first die and the second die.

17. The multi-chip flip chip package of claim 12, further comprising:
a substrate attached to the second surface of the first die and the second surface of the second die.

18. The multi-chip flip chip package of claim 13, wherein the conducting elements of the second conducting group are positioned on a same plane.

19. The multi-chip flip chip package of claim 14, wherein the conducting elements of the second conducting group are positioned on a same plane.

20. The multi-chip flip chip package of claim 14, further comprising:
a second dielectric element positioned between the conducting elements of the second conducting group and at least one of the first die and the second die.
